(19) United States
(12) Patent Application Publication
(10) Pub. No.: US 2024/0355619 A1
(43) Pub. Date: Oct. 24, 2024

(54) SEMICONDUCTOR MATERIAL WAFERS OPTIMIZED FOR LINEAR AMPLIFIERS

(71) Applicant: MACOM Technology Solutions Holdings, Inc., Lowell, MA (US)

(72) Inventors: Kevin James LINTHICUM, Lowell, MA (US); Prity Kirit PATEL, Lowell, MA (US); John Claassen ROBERTS, Lowell, MA (US); David Walter RUNTON, Lowell, MA (US)

(21) Appl. No.: 18/685,616

(22) PCT Filed: Aug. 23, 2022
(86) PCT No.: PCT/US2022/041231

§ 371 Date: Feb. 22, 2024

Related U.S. Application Data
(60) Provisional application No. 63/240,562, filed on Sep. 3, 2021.

(51) Int. Cl. H01L 21/02; H01L 29/16; H01L 29/778; H03F 1/02

(52) U.S. Cl. CPC H01L 21/02378; H01L 21/02458; H01L 21/02505; H01L 21/0254; H03F 1/0288; H01L 29/1608; H01L 29/7786; H03F 2200/451

(57) ABSTRACT

A number of different types of semiconductor material structures and wafers, including epiwafers, are described herein. The semiconductor material wafers are optimized in certain aspects to form transistor amplifiers for use with new modulation communications systems. A semiconductor material wafer includes a silicon carbide substrate and at least one III-nitride material layer over the silicon carbide substrate. The semiconductor material wafers can include layers consisting of semiconductor materials without dopants such as iron or carbon, formed over the silicon carbide substrate.

### CROSS-REFERENCE TO RELATED APPLICATION(S)

This application is a U.S. National Stage Application of International Application No. PCT/US2022/041231, filed Aug. 23, 2022, which claims the benefit of U.S. Provisional Patent Application No. 63/240,562, filed Sep. 3, 2021, which is incorporated by reference herein in their entireties.

### BACKGROUND

Integrated circuit power amplifiers are essential in mobile communications applications because of the high-performance demands related to output power, signal linearity, signal gain, bandwidth, and efficiency. Because of their wide bandgap, gallium nitride (GaN) materials have proven useful for fabricating amplifiers in mobile communications applications.

Amplifiers are formed from at least one transistor, and oftentimes, formed from an interconnection of multiple transistors. The ability and suitability of a particular amplifier to support mobile communications ultimately depend on the design of the amplifier, including the semiconductor materials used to form the transistors used in the amplifier. Indeed, one important aspect of transistor performance is the composition of the semiconductor wafers that the transistors are formed upon. The semiconductor wafers can be manufactured in a number of different ways, including through the use of epitaxial growth.

A semiconductor wafer including epitaxially-grown layers can be referred to as an epiwafer. An epiwafer can include a number of different layers formed over a base substrate of silicon (Si), silicon carbide (SiC), sapphire (Al₂O₃), or other base materials. These base substrates may also be composite substrates consisting of various other materials but having a top surface or surface layer consisting of silicon, silicon carbide, or sapphire.

The respective material compositions of the semiconductor materials, the dopants (either unintentional impurities or intentionally added dopants) used in the layers, the arrangement of the layers, the thicknesses of the layers, and other material and structural aspects of an epiwafer all contribute to the performance characteristics of transistors (and thus amplifiers) formed using the epiwafer. Thus, the correct selection of the above variables of the epiwafer is important to optimizing transistor, and therefore amplifier, performance.

Impurities or dopants in the layers of an epiwafer can act as electron and hole traps which impede conduction, as compared to ideal conduction. Each type of trap is associated with a unique activation energy, capture cross section, and time constant, based on the trapping and de-trapping behavior of the impurity. Thus, a transistor formed using one type of epiwafer might be more (or less) suitable for a certain mobile communication technique, as compared to another transistor formed using another type of epiwafer, based on the inclusion of unintentional impurities or intentionally added dopants.

The performance of an amplifier in RF transmission applications can be measured in a variety of ways. In the context of advanced signal modulation schemes, one important parameter is the need to minimize adjacent channel power (ACP) spurs that occur across the frequency spectrum. Another important goal is to limit the error vector magnitude (EVM) percentage. Such ACP spurs and high EVM percentages can be observed when using transistors formed from conventional prior art epiwafers.

To see this effect, FIG. 1 illustrates periods of transmission by an amplifier of a base station in a radio access network over time using a time division duplex (TDD) mobile communications technique. The TDD mobile communications technique requires an amplifier to output a signal in discrete time periods 10-14. The amplifier is turned on during the periods of transmission 10-14, which corresponds to when the base station is transmitting. The amplifier is turned off, and does not transmit, during other periods.

An amplifier can have lowered performance during the turn-on transition 10A shown in FIG. 1, for example, when the amplifier is transitioned from off to on. Peak EVM percentage usually occurs during the transition 10A, but rapidly decreases thereafter in the remainder of the pulse.

FIG. 2A illustrates an example ACP of a signal transmitted by an amplifier formed on a prior art GaN-on-Si epiwafer wafer (as further described below in FIG. 4A) at a time instant shortly after the amplifier is turned on at the transition 10A shown in FIG. 1. Because digital predistortion was applied to the signal in FIG. 2A, the power in adjacent channels does not include significant peaks, spurs, or other characteristics related to distortion. This preferred linearized ACP performance is due in part to the absence of unwanted traps in the GaN material layers. However, a disadvantage of using amplifiers consisting of GaN-on-Si epiwafers is the more challenging design criteria needed to meet some of the more stringent thermal requirements when operated at elevated channel and flange temperatures required for extreme applications in base stations.

In contrast to FIG. 2A, FIG. 2B illustrates the linearized ACP of a signal transmitted by an amplifier formed on a prior art GaN-on-SiC epiwafer (as further described below in FIG. 3) at the transition 10A shown in FIG. 1. Digital predistortion was also applied to the signal in FIG. 2B, but the power in adjacent channels includes peaks, spurs, or other characteristics related to distortion. A number of spurs 20-22 are shown in FIG. 2B. The spurs are indicators of unwanted distortion of the amplified signal, at a time instant shortly after the amplifier is turned on at the transition 10A. This distortion can subside later in time, after the amplifier has been operating (e.g., further into the period of transmission 10 shown in FIG. 1). The distortion can also result in deteriorated EVM in wireless communications. EVM is a measure of modulation quality and error performance in mobile communications systems.

FIG. 3 illustrates a cross section of a typical prior art epiwafer 100 with an SiC substrate. The wafer 100 includes a substrate 110 and one or more layers 112 over the substrate 110. The substrate 110 in FIG. 3 can be embodied as an SiC substrate. The layers 112 can be formed through epitaxial growth, such as metalorganic vapor-phase epitaxy (MOVPE), metal organic chemical vapor deposition (MOCVD), molecular beam epitaxy (MBE), and other techniques. The layers 112 can include one or more layers of III-nitride material(s).

As shown in FIG. 3, the layers 112 can include a nucleation layer 120, a region or layer of GaN 130, a sub-barrier layer 140, a barrier layer 150, and a cap layer 160. The nucleation layer 120 can be embodied as a layer of aluminum nitride (AlN). The total combined thickness of layers 112 can have a thickness from 1000-2200 nanometers (nm).

The region or layer of GaN 130 includes certain dopants, such as iron and/or carbon. The layer of GaN 130 can have a thickness designed to meet certain vertical breakdown or voltage requirements of a transistor (among possibly several transistors), as well as achieving certain crystalline defect density levels formed on the wafer 100. It is well known that when using heteroepitaxial growth methods for semiconductor materials, such as III-nitride growth on silicon and silicon carbide substrates, crystalline imperfections, such as threading defect dislocations, will result due to the misalignment of atoms stemming from differences in lattice constants. As such, by growing the GaN material thicker, defect bending and defect annihilation can occur reducing the number of threading defects which reach the top surface of the epiwafer and compromise the performance of transistors formed on the epiwafer.

However, typically, for a transistor formed on the wafer 100, the thicker GaN layer 130 will result in increased parasitic leakage levels for the transistor, which may also be deleterious to the operation of the transistor. As such, it is common to intentionally add impurities (such as iron, carbon, or other impurities) to the GaN layer 130 which act to make the GaN layer more resistive and reduce the parasitic leakage levels for the transistor. To summarize, the prior art epiwafer of FIG. 3 is generally a thick GaN layer formed atop a silicon carbide substrate. Because thick GaN layers then result in undesirable parasitic leakage, dopants, such as iron or carbon, are intentionally added.

FIG. 4A illustrates a section of another prior art GaN-on-Si epiwafer 200. As described below, iron is not intentionally added when the layers of the epiwafer 200 are formed. Carbon is also not intentionally added in the layer of GaN 250 but may intentionally be added in the underlying transition layers 230 and 240.

The wafer 200 includes a silicon substrate 210 and one or more layers 212 over the substrate 210. As shown in FIG. 4A, the layers 212 include a nucleation layer 220, a first transition layer 230, a second transition layer 240, a region or layer of GaN 250, a barrier layer 260, and a cap layer 270. The layer of GaN 250 can have a thickness of between about 400 nm to 1000 nm. In this prior art, the GaN 250 is undoped.

Referring next to FIG. 4B, yet another prior art epiwafer is shown. This epiwafer is generally described in “Thin Al_{0.5}Ga_{0.5}N/GaN HEMTs on QuanFINE Structure” by Chen et al. (2020). The epitaxial layers were grown on an SiC substrate 211 utilizing a MOCVD process. Next, a low thermal boundary-resistance AlN nucleation layer 221 was grown. Atop the nucleation layer 221 is a thin 250 nm GaN layer 251 that is not intentionally doped with iron. On top of this, a 5.0 nm Al_{0.5}Ga_{0.5}N barrier layer 261, and a 1.5 nm cap layer 271 are provided as the active layers. Note that the GaN layer 251 is purposely made to be significantly thinner (at 250 nm) than the prior art of FIGS. 3 and 4A. It is believed that the prior art of FIG. 4B uses a thin 250 nm GaN layer in order to effectively replace the need for an underlying GaN-based iron or carbon doped backbarrier with that of the underlying AlN layer 221 to provide for carrier confinement in the thinner GaN layer 251 to suppress buffer drain leakage current, short channel effects, and allowing for improved device pinch-off.

As can be seen above, prior art epiwafers are thus either: (1) a relatively thick iron or carbon doped GaN layer over SiC (FIG. 3); (2) a relatively thick undoped GaN layer on silicon (FIG. 4A); or (3) a relatively thin undoped GaN layer over SiC (FIG. 4B). Each of these epiwafer structures suffer from performance drawbacks that the present invention addresses.

### SUMMARY

The epiwafer is comprised of a silicon carbide substrate, a nucleation layer over the silicon carbide substrate, a gallium nitride layer over the nucleation layer having a thickness of greater than 600 nm, and a concentration of iron that is less than or equal to 1×10¹⁶ cm⁻³. The epiwafer also has a barrier layer over the gallium nitride layer and a cap layer over the barrier layer.

Transistors formed in or on an epiwafer are also disclosed. Additionally, a Doherty amplifier comprising a peaking amplifier and a main amplifier, wherein at least one amplifier in the Doherty power amplifier is assembled from at least one transistor that was formed in or on an epiwafer are disclosed.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates periods of radio signal transmission by a base station in a radio access network over time using a mobile communications technique.

FIG. 2A illustrates the adjacent channel power of a linearized signal transmitted by a base station using an amplifier formed on a GaN-on-Si semiconductor material wafer at a time instant after turn-on.

FIG. 2B illustrates the adjacent channel power of a linearized signal transmitted by a base station using an amplifier formed on a GaN-on-SiC semiconductor material wafer at a time instant after turn-on.

FIG. 3 illustrates a section of a prior art semiconductor material wafer with a silicon carbide substrate, with one or more semiconductor material layers, including an iron doped layer.

FIG. 4A illustrates a section of a prior art semiconductor material wafer with a silicon substrate and an GaN epilayer that is not intentionally doped with any dopant.

FIG. 4B illustrates a section of another prior art semiconductor material wafer having a silicon carbide substrate and a very thin GaN layer without iron doping.

FIG. 5 illustrates a section of semiconductor material wafer with a silicon carbide substrate, without iron or carbon intentionally included in the semiconductor material layers, according to aspects of certain embodiments of the present invention.

FIG. 6 illustrates a section of another semiconductor material wafer with a silicon carbide substrate, without iron intentionally included in the semiconductor material layers, according to aspects of certain embodiments of the present invention.

FIG. 7 illustrates a section of another semiconductor material wafer with a silicon carbide substrate, without iron intentionally included in the semiconductor material layers, according to aspects of certain embodiments of the present invention.

FIG. 8 illustrates an example Doherty amplifier according to various embodiments described herein.

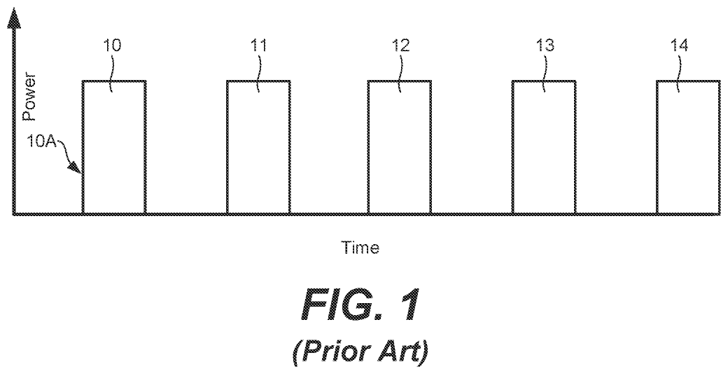

### DETAILED DESCRIPTION

Epiwafers are described herein with improved performance for certain amplifier designs as compared to the prior art. According to the embodiments, the epiwafers include a silicon carbide (SiC) substrate and at least one III-nitride material epitaxial layer formed over the SiC substrate. The presence of any iron in the semiconductor material wafers is unintentional, and there is no intentional doping with iron. The presence of any carbon in III-nitride layers near the barrier or sub-barrier semiconductor material is also unintentional, and there is no intentional doping with carbon. Furthermore, the total thickness of the III-nitride material is at least 600 nm thick in order to reduce threading dislocation defect densities and crystalline imperfections, thereby reducing any additional deep traps associated with threading dislocation defects which may contribute in part with the traps associated with iron and carbon doping to cause unwanted distortions, such as ACP spurs and deteriorated EVM, in RF transistors and amplifiers.

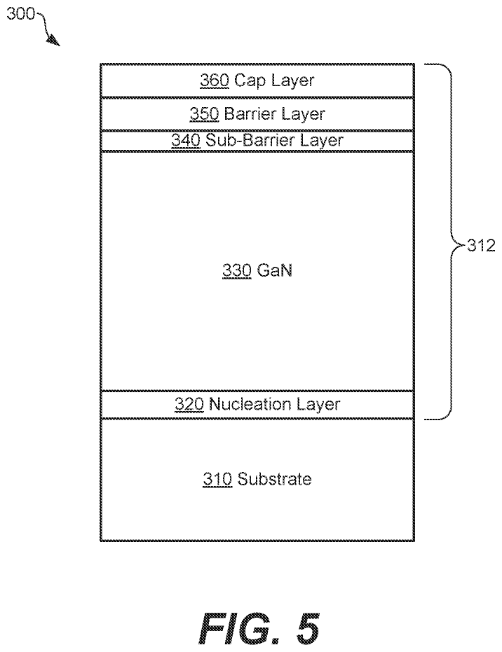

In one case, a semiconductor material wafer includes at least one III-nitride layer consisting primarily of GaN over the SiC substrate. However, the teachings of the present invention are not limited to GaN layers, and may include alloys of GaN (such as AlGaN) or other III-nitride layers. As described below, the semiconductor wafers shown in FIGS. 5-7 are optimized in certain aspects to enable the formation of amplifiers for use with mobile communication systems, among other applications.

FIG. 5 illustrates a cross section of semiconductor material structure or wafer 300 with an SiC substrate, without iron or carbon intentionally included in the semiconductor material layers, according to aspects of the embodiments described herein. Note that the term “SiC substrate” as used herein refers to not only a substrate that is wholly comprised of SiC, but also a substrate that is a composite of layers of varying materials, including one layer that is SiC. Thus any substrate with at least one layer that is primarily SiC would be considered a “SiC substrate.”

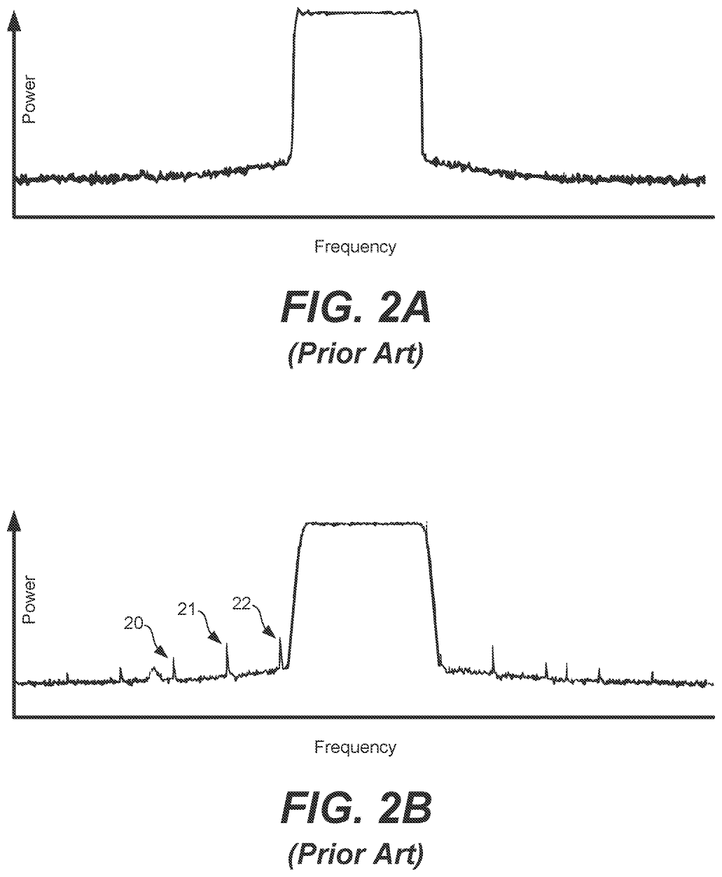

The wafer 300, and the layers of the wafer 300, are not drawn to scale in FIG. 5. In one embodiment, no other layers beyond those shown in FIG. 5, in the wafer 300, are relied upon or included, and the wafer 300 consists only of the layers shown in FIG. 5 and described below. In other cases, the wafer 300 can include other layers in addition to those shown in FIG. 5. In other cases, one or more of the layers of the wafer 300, such as the sub-barrier layer 340 and/or cap layer 360 can be omitted. When transistors are formed (i.e., formed in or on) using the wafer 300, the transistors do not exhibit (or exhibit less of) the type of distortion described above with reference to FIG. 2B.

The wafer 300 includes a substrate 310 and one or more layers 312 over the substrate 310. The substrate 310 in FIG. 5 can be an SiC substrate, such as a 4H-SiC polytype substrate, a 6H-SiC polytype substrate, or a 3C-SiC polytype substrate, among other types of polytype substrates. The substrate 310 can be between 80-300 mm in diameter, although other diameters can be relied upon. It may be desirable that the substrate 310 have high resistivity, and in some embodiments, it may be preferred that the substrate 310 resistivity be >1E7 ohm-cm. The layers 312 can be formed through epitaxial growth, such as MOCVD, MBE, or other techniques. The layers 312 can include one or more layers of III-nitride material(s). The combined total thickness of layers 312 can have a thickness from 600-1200 nm, or a narrow range, such as 700-1000 nm, and in one example may be 800-850 nm, although other thicknesses can be relied on.

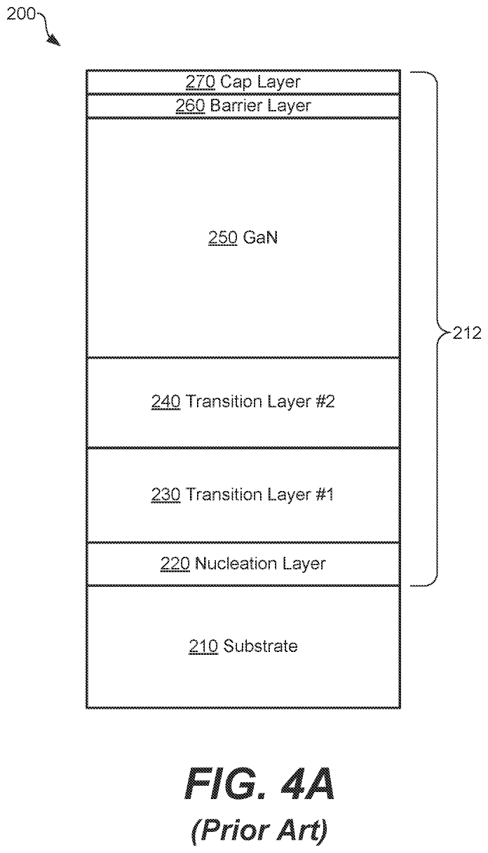

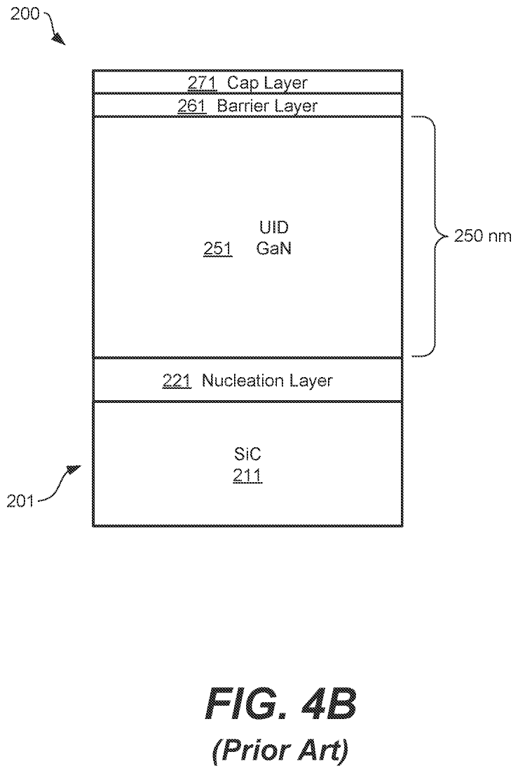

In general, and in contrast to the prior art, the thickness of the layers 312 is greater than the thinner epitaxial layers of the prior art (as exemplified by FIG. 4B). This results, in part, from the novel discovery that in certain RF applications, a thicker epitaxial layer 312 on silicon carbide that is devoid of intentional iron or carbon doping, as well as reduced threading dislocation defects and associated threading dislocation defect traps, will result in higher performing amplifier structures. This is despite the increase in parasitic leakage current in a thicker epitaxial layer 312. It has been found by the inventors that the increase in other performance parameters offsets any deleterious effects of leakage.

For example, typically, the thicker III-nitride materials are, the lower the threading dislocation defect densities that can be achieved. These threading dislocation defects can lead to increased concentrations of unintentional carbon impurity complexes which, along with the threading defect itself, act as additional traps and contribute to the unwanted distortions shown in FIG. 2B. Additionally, higher defect densities in the vicinity of the two-dimensional electron gas (2DEG) and surface region of the transistor used to form the amplifier can lead to less-than-ideal electronic transport properties, shorter lifetimes, and less robust device reliability. Although the resulting carrier confinement is not ideal due to the thicker channel regions, the resulting leakage levels and pinch-off capability of the devices fall within acceptable limits for use in RF amplifiers.

As described earlier in the prior art, due to the nature of heteroepitaxial growth of III-nitride material on silicon carbide substrates, the crystalline quality of layers 312 will include a certain level of threading dislocation defects. The specific concentration of threading dislocation defects will depend in part on the total thickness of layer 312; generally, the greater the total thickness of these combined layers, the lower the concentration of threading defects and associated traps at the near surface region of the epiwafer. These threading dislocations generally are comprised of pure edge dislocations, screw dislocations and mixed (screw and edge) dislocations.

Referring to FIG. 5, generally the bulk of the thickness of layers 312 is from the thickness of GaN layer 330, as the nucleation layer 320, sub-barrier layer 340, barrier layer 350, and GaN cap 360 are all relatively thin layers compared to GaN layer 330. For example, if the combined thickness of layers 312 are 1800 nm thick, the total threading dislocation defect density at the near surface region of the epiwafer 300 is approximately 6.5E+8. Note that defect densities, as is known to those of ordinary skill in the art, are in units of per square centimeter (i.e., /cm²), whereas concentrations, as is known to those of ordinary skill in the art, are in units of per cubic centimeter (i.e., /cm³). If the combined thickness of layers 312 is reduced to 1500 nm thick, the total threading dislocation defect density at the near surface region of the epiwafer 300 increases to approximately 1.5E+9. If the combined thickness of layers 312 is further reduced to 800 nm thick, the total threading dislocation defect density at the near surface region of the epiwafer 300 further increases in range to approximately 1.5-2.5E+9. As the total thickness of the combined layers 312 continues to decrease, the total threading dislocation defect density at the near surface region of the epiwafer 300 will further increase as will the total concentration of threading defect associated traps which can in part act to distort the transistor and amplifier performance and add to ACP spurs and deteriorated EVM.

As shown in FIG. 5, the layers 312 include a nucleation layer 320, a region or layer of GaN 330 (or an alloy of GaN), a sub-barrier layer 340, a barrier layer 350, and a cap layer 360. The nucleation layer 320 can be embodied as a layer of AlN. The nucleation layer 320 can have a thickness of between 5-150 nm, or a narrower range, such as between 5-20 nm. In one example, the nucleation layer 320 can have a thickness of 12-18 nm, although other thicknesses can be relied upon. The layer of GaN 330 can have a thickness of between about 600 nm to 1000 nm. Thus, the combined thickness of layers 312 will be slightly greater than 600 nm, taking into account the other thinner layers making up the layers 312. In another example, the layer of GaN 330 can have a thickness of 800 nm, although other thicknesses can be relied upon. In general though, the GaN layer should be no thinner than about 600 nm.

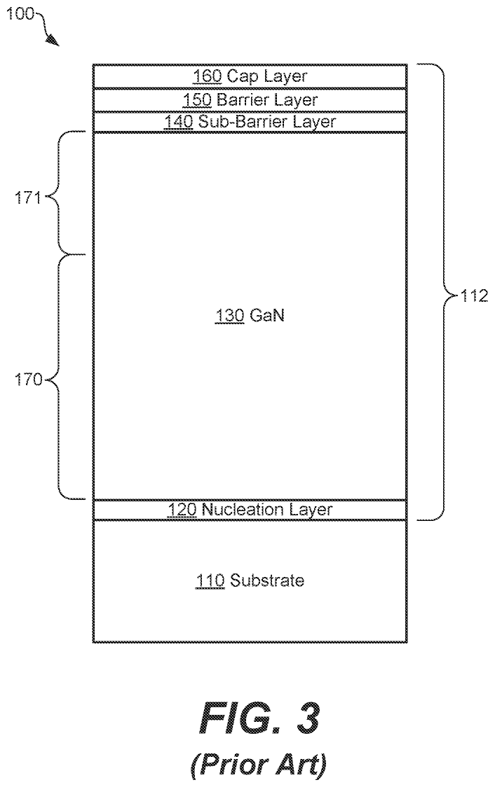

In one embodiment, the layer of GaN 330 can be embodied as a GaN or GaN-like material (such as GaN alloys or other III-nitride materials) that is not intentionally doped with iron and/or carbon. Particularly, the presence of any iron or carbon in the layer of GaN 330 is unintentional, and the layer of GaN 330 can consist primarily of GaN. Preferably, in this case, the entire layer of GaN 330 is free from iron, such that concentration levels of iron in the entire layer of GaN 330, if any, can be less than detectability limits, with the current capability to detect iron at or above about 7×10¹⁴ cm⁻³, for example. This is in contrast to other GaN-on-SiC structures in which iron is typically intentionally added, such as the intentional concentration of iron in the portion 170 of the GaN layer 130 shown in FIG. 3, which can be between 4×10¹⁷ cm⁻³ to 5×10¹⁷ cm⁻³. This is also in contrast to the concentration of iron in the portion 171 of the GaN layer 130 shown in FIG. 3.

The layer of GaN 330 can also be free of intentionally doped carbon. Unlike iron which needs to be intentionally added from an external source, carbon exists in the growth environment during GaN growth as the carbon impurities are a byproduct of the metalorganic gallium source and other group III sources used in MOCVD growth of III-nitrides. However, with careful control over the growth environment (temperature, pressure, III/V ratios, etc.) the unwanted incorporation of carbon into the resulting layer of GaN 330 can be minimized such that the concentration of carbon in a layer of GaN 130 can be kept below detectability limits, or below 1×10¹⁶ cm⁻³. It may be preferred that the carbon concentration in a layer of GaN 330 be between 1×10¹⁶ cm⁻³ to 5×10¹⁶ cm⁻³. Generally speaking, to reduce the unintended incorporation of carbon impurities into MOCVD grown GaN material, it is desirable to increase one or a combination of the growth temperature, the III/V ratio and or the chamber pressure.

As described above in the prior art, iron and/or carbon are typically intentionally added to thicker GaN-on-SiC structures, such as the layer of GaN 130 shown in FIG. 3 and other GaN layers of about 500 nm or thicker. Iron and or carbon can be added to improve carrier confinement, increase the breakdown voltage, and reduce unwanted leakage of transistors and other devices formed on semiconductor material wafers including thicker GaN-on-SiC structures, by compensating the GaN layer and making it more resistive. In the example shown in FIG. 5, the undoped layer of GaN 330 is about 800 nm thick, however the resulting transistor and amplifier leakage is still acceptable, therefore, it is not necessary to compensate or make the layer of GaN 330 more resistive. In certain embodiments, the undoped layer of GaN 330 is between 600 nm-1000 nm thick.

Concentration levels of iron and carbon in the layer of GaN 330 can be particularly low (or the lowest throughout layer of GaN 330) at or near the interface between the layer of GaN 330 and the sub-barrier layer 340. If the sub-barrier layer 340 is omitted, concentration levels of iron and carbon in the layer of GaN 330 can be particularly low (or the lowest throughout the layer of GaN 330) at or near the interface between the layer of GaN 330 and the barrier layer 350. Thus, the iron concentration in the layer of GaN 330 at or near the interface with the sub-barrier layer 340 can be less than the current detectability limit of 7×10¹⁴ cm⁻³. In other examples, the iron concentration throughout the layer of GaN 330 or in a portion at or near the interface with the sub-barrier layer 340 can be less than the current detectability limit of 7×10¹⁴ cm⁻³. In other cases, the iron concentration throughout the layer of GaN 330 or in a portion at or near the interface with the sub-barrier layer 340 can be less than or equal to 1×10¹⁵ cm⁻³, or less than or equal to 1×10¹⁶ cm⁻³. In still other cases, the iron concentration throughout the layer of GaN 330 at or near the interface with the sub-barrier layer 140 can be less than 3×10¹⁶ cm⁻³, less than 4×10¹⁶ cm⁻³, or less than 5×10¹⁶ cm⁻³.

Similarly, the carbon concentration in the layer of GaN 330 at or near the interface with the sub-barrier layer 340 can be less than the current detectability limit of 1×10¹⁶ cm⁻³. In other cases, the carbon concentration throughout the layer of GaN 330 or in a portion at or near the interface with the sub-barrier layer 340 can be less than or equal to 3×10¹⁶ cm⁻³, or less than or equal to 5×10¹⁶ cm⁻³.

The sub-barrier layer 340 can be embodied as a layer of AlN. The sub-barrier layer 340 is optional and can be omitted in some cases, such as the example shown in FIG. 4A. The sub-barrier layer 340 can have a thickness of between 1-5 nm. In one example, the sub-barrier layer 340 can have a thickness of 1 nm.

The barrier layer 350 can be embodied as a layer of AlGaN. The barrier layer 350 can have a thickness of between 5-30 nm, or a narrower range, such as between 5-25 nm or between 10-20 nm. In one example, the barrier layer 350 can have a thickness of 18 nm. The ratio of aluminum to gallium in the barrier layer 350 can be 25% aluminum to 75% gallium, for Al_{0.25}Ga_{0.75}N, although the ratio can vary. In other cases, the ratio of aluminum to gallium in the barrier layer 350 can range from 23-27% aluminum, with the balance gallium, and other ratios can be relied upon. The cap layer 360 can be embodied as a layer of GaN. The cap layer 360 is optional and can be omitted in some cases. The cap layer 360 can have a thickness of between 1-4 nm.

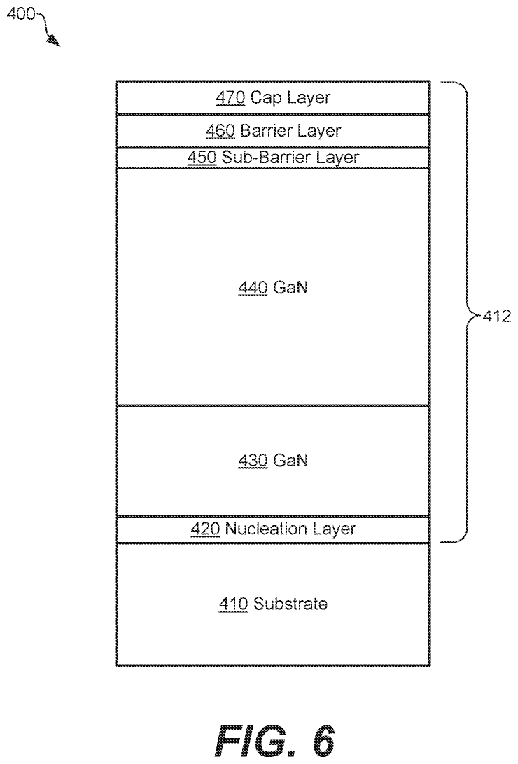

FIG. 6 illustrates a section of semiconductor material wafer 400 with a silicon carbide substrate, without iron in the semiconductor material layers, according to aspects of the embodiments described herein. However, in this embodiment, carbon is intentionally added to a specific layer, namely layer 430, of the semiconductor material layers. The wafer 400, and the layers of the wafer 400, are not drawn to scale in FIG. 6. In one embodiment, no other layers beyond those shown in FIG. 6, in the wafer 400, are relied upon or included, and the wafer 400 consists only of the layers shown in FIG. 6 and described below. In other cases, the wafer 400 can include other layers in addition to those shown in FIG. 6. In other cases, one or more of the layers of the wafer 400, such as the sub-barrier layer 450, can be omitted. When transistors are formed (i.e., formed in or on) using the wafer 400, the transistors do not exhibit (or exhibit less of) the type of distortion described above with reference to FIG. 2B.

The wafer 400 includes a substrate 410 and one or more layers 412 over the substrate 410. The substrate 410 in FIG. 6 can be embodied as an SiC substrate, formed in any suitable way or obtained or sourced from a vendor. The substrate 410 can be a 4H-SiC substrate in one case. In other cases, the substrate 410 can be a 6H-SiC substrate or a 3C-SiC polytype substrate. The substrate 410 can be between 80-300 mm in diameter. It may be desirable that the substrate 410 have high resistivity, and in some embodiments it may be preferred that the substrate 410 resistivity be >1E7 ohm-cm. The layers 412 can be formed through epitaxial growth, such as MOCVD, MBE, or other techniques. The layers 412 can include one or more layers of III-nitride material(s). The combined total thickness of layers 412 can have a thickness from 900-1700 nm, or a narrow range, such as 1000-1500 nm, and in one example may be 1200-1250 nm, although other thicknesses can be relied on.

As similarly described earlier in reference to FIG. 5, due to the nature of heteroepitaxial growth of III-nitride material on silicon carbide substrates, the crystalline quality of layers 412 will include a certain level of threading dislocation defects. The specific concentration of threading dislocation defects will depend in part on the total thickness of layer 412; generally, the thicker the total thickness of these combined layers is, the lower the concentration of threading dislocation defects and associated traps that will result at the near surface region of the epiwafer. For example, if the combined thickness of layers 412 are 1800 nm thick, the total threading dislocation defect density at the near surface region of the epiwafer 400 is approximately 6.5E+8. However, if the combined thickness of layers 412 is reduced to 1500 nm thick, the total threading dislocation defect density at the near surface region of the epiwafer 400 increases to approximately 1.5E+9. If the combined thickness of layers 412 is further reduced to 1200 nm thick, the total threading dislocation defect density at the near surface region of the epiwafer 400 further increases in range to approximately 1.5-2.0E+9. As the total thickness of the combined layers 412 continues to decrease, the total threading dislocation defect density at the near surface region of the epiwafer 400 will further increase, as will the total concentration of threading dislocation defect associated traps which can in part act to distort the transistor and amplifier performance and add to ACP spurs and deteriorated EVM.

As shown in FIG. 6, the layers 412 include a nucleation layer 420, a region or layer of GaN 430, a second region or layer of GaN 440, a sub-barrier layer 450, a barrier layer 460, and a cap layer 470. The nucleation layer 420 can be embodied as a layer of AlN. The nucleation layer 420 can have a thickness of between 5-150 nm.

The region or layer of GaN 430 can have a thickness of between about 300 nm to 500 nm. In one example, the layer of GaN 430 can have a thickness of 400 nm, although other thicknesses can be relied upon. The layer of GaN 430 does not include iron (or the presence of any iron in the layer of GaN 430 is unintentional), but the layer of GaN 430 can include a dopant, such as carbon, at a density of between 1.0×10¹⁸ cm⁻³ to 5.0×10¹⁸ cm⁻³. In one case, the layer of GaN 430 can include carbon at a density of between 2×10¹⁸ cm⁻³ to 3×10¹⁸ cm⁻³.

The second region or layer of GaN 440 can have a thickness of between about 600 nm to 1000 nm thick. In one embodiment, the layer of GaN 440 can be embodied as a GaN or GaN-like material that is not intentionally doped with iron and/or carbon. Particularly, the presence of any iron or carbon in the layer of GaN 440 is unintentional, and the layer of GaN 440 can consist primarily of GaN. Preferably, in this case, the entire layer of GaN 440 can be essentially free of iron and carbon, such that concentration levels of iron and/or carbon in the entire layer of GaN 440 can be at or below detectability limits. In other cases, concentration levels of iron and carbon in the layer of GaN 440 can be particularly low (or the lowest throughout layer of GaN 440) at or near the interface between the layer of GaN 440 and the sub-barrier layer 450. If the sub-barrier layer 450 is omitted, concentration levels of iron and carbon in the layer of GaN 440 can be particularly low (or the lowest throughout layer of GaN 440) at or near the interface between the layer of GaN 440 and the barrier layer 460. In other examples, the iron concentration throughout the layer of GaN 440 or at or near the interface with the sub-barrier layer 450 can be less than the current detectability limit. In other cases, the iron concentration throughout the layer of GaN 440 at or near the interface with the sub-barrier layer 450 can be less than or equal to 1×10¹⁵ cm⁻³, or less than or equal to 1×10¹⁶ cm⁻³. In still other cases, the iron concentration throughout the layer of GaN 440 or at or near the interface with the sub-barrier layer 450 can be less than 3×10¹⁶ cm⁻³, less than 4×10¹⁶ cm⁻³, or less than 5×10¹⁶ cm⁻³. In these examples, the iron can be intentionally added (in small amounts) or unintentionally present. Similarly, the carbon concentration in the second layer of GaN 440 at or near the interface with the sub-barrier layer 450 can be less than the current detectability limit of 1×10¹⁶ cm⁻³. In other cases, the carbon concentration throughout the layer of GaN 440 or in a portion at or near the interface with the sub-barrier layer 450 can be less than or equal to 3×10¹⁶ cm⁻³, or less than or equal to 5×10¹⁶ cm⁻³.

The sub-barrier layer 450 can be embodied as a layer of AlN. The sub-barrier layer 450 can have a thickness of between 1-5 nm. The barrier layer 460 can be embodied as a layer of AlGaN. The barrier layer 460 can have a thickness of between 5-30 nm. The ratio of aluminum to gallium in the barrier layer 460 can be 25% aluminum to 75% gallium, for Al_{0.25}Ga_{0.75}N, although the ratio can vary. In other cases, the ratio of aluminum to gallium in the barrier layer 460 can range from 23-27% aluminum, with the balance gallium, and other ratios can be relied upon. The cap layer 470 can be embodied as a layer of GaN. The cap layer 470 is optional and can be omitted in some cases. The cap layer 470 can have a thickness of between 1-4 nm.

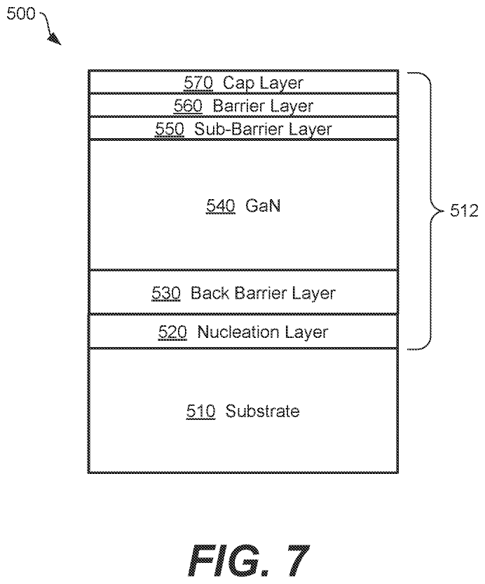

FIG. 7 illustrates a section of semiconductor material wafer 500 with a silicon carbide substrate, without iron in the semiconductor material layers, according to aspects of the embodiments described herein. In one embodiment, no other layers beyond those shown in FIG. 7, in the wafer 500, are relied upon or included, and the wafer 500 consists only of the layers shown in FIG. 7 and described below. In other cases, the wafer 500 can include other layers in addition to those shown in FIG. 7. In other cases, one or more of the layers of the wafer 500, such as the sub-barrier layer 550, can be omitted. When transistors are formed (i.e., formed in or on) using the wafer 500, the transistors do not exhibit (or exhibit less of) the type of distortion described above with reference to FIG. 2B.

The wafer 500 includes a silicon carbide substrate 510 and one or more layers 512 over the substrate 510. The substrate 510 can be a 4H-SiC polytype substrate in one case. In other cases, the substrate 510 can be a 6H-SiC substrate or a 3C-SiC polytype substrate. The substrate 510 can be between 80-300 mm in diameter. It may be desirable that the substrate 510 have high resistivity, and in some embodiments, it may be preferred that the substrate 510 resistivity be >1E7 ohm-cm. The layers 512 can be formed through epitaxial growth, such as MOCVD, MBE, or other techniques. The layers 512 can include one or more layers of III-nitride material(s). The combined total thickness of layers 512 can have a thickness from 900-1700 nm.

As similarly described earlier with respect to FIGS. 5 and 6, due to the nature of heteroepitaxial growth of III-nitride material on silicon carbide substrates, the crystalline quality of layers 512 will include a certain level of threading dislocation defects. The specific concentration of threading dislocation defects will depend in part on the total thickness of layer 512; generally, the thicker the total thickness of these combined layers is, the lower the concentration of threading dislocation defects and associated traps that will result at the near surface region of the epiwafer. For example, if the combined thickness of layers 512 are 1800 nm thick, the total threading dislocation defect density at the near surface region of the epiwafer 500 is approximately 6.5E+8. However, if the combined thickness of layers 512 is reduced to 1500 nm thick, the total threading dislocation defect density at the near surface region of the epiwafer 500 increases to approximately 1.5E+9. If the combined thickness of layers 512 is further reduced to a thickness of 1200 nm, the total threading dislocation defect density at the near surface region of the epiwafer 500 further increases in range to approximately 1.5-2.0E+9. As the total thickness of the combined layers 512 continues to decrease, the total threading dislocation defect density at the near surface region of the epiwafer 500 will further increase, as will the total concentration of threading dislocation defect associated traps which can in part act to distort the transistor and amplifier performance and add to ACP spurs and deteriorated EVM.

As shown in FIG. 7, the layers 512 include a nucleation layer 520, a back barrier layer 530, a region or layer of GaN 540, a sub-barrier layer 550, a barrier layer 560, and a cap layer 570. The nucleation layer 520 can be embodied as a layer of AlN. The nucleation layer 520 can have a thickness of between 5-150 nm.

The back barrier layer 530 can have a thickness of between about 300 nm to 500 nm thick. In one example, the back barrier layer 530 can have a thickness of 400 nm, although other thicknesses can be relied upon. The back barrier layer 530 can be embodied as a layer of AlGaN. The ratio of aluminum to gallium in the back barrier layer 530 can be between 2-6% aluminum to 98-94% gallium, as examples. In one case, the ratio of aluminum to gallium in the back barrier layer 530 can be 4% aluminum to 96% gallium, for Al_{0.04}Ga_{0.96}N, although the ratio can vary. The back barrier layer 530 does not include iron (or the presence of any iron in the layer of back barrier layer 530 is unintentional). Thus, the iron concentration in the back barrier layer 530 can be less than the current detectability limit of 7×10¹⁴ cm⁻³. In other cases, the iron concentration throughout the back barrier layer 530 can be less than or equal to 1×10¹⁵ cm⁻³, or less than or equal to 1×10¹⁶ cm⁻³. In still other cases, the iron concentration throughout the back barrier layer of GaN 530 can be less than 3×10¹⁶ cm⁻³, less than 4×10¹⁶ cm⁻³, or less than 5×10¹⁶ cm⁻³.

It may be preferred in certain embodiments that the back barrier layer 530 be intentionally doped with carbon. In this embodiment, the back barrier layer 530 does not include iron (or the presence of any iron in the back barrier 530 is unintentional), but the back barrier layer 530 does include intentionally doped carbon at a density of between 1.0×10¹⁸ cm⁻³ to 5.0×10¹⁸ cm⁻³. In one case, the back barrier layer 530 can include carbon at a density of between 2×10¹⁸ cm⁻³ to 3×10¹⁸ cm⁻³.

The layer of GaN 540 can have a thickness of between about 600 nm to 1000 nm thick. In one example, the layer of GaN 540 can have a thickness of 800 nm, although other thicknesses can be relied upon. In one embodiment, the layer of GaN 540 can be embodied as a GaN or GaN-like material that is not intentionally doped with iron and/or carbon. Particularly, the presence of any iron or carbon in the layer of GaN 540 is unintentional, and the layer of GaN 540 can consist essentially of GaN. Preferably, in this case, the entire layer of GaN 540 can be essentially free of iron and carbon, such that concentration levels of iron and carbon in the entire layer of GaN 540 can be at or below detectability limits. In other cases, concentration levels of iron and carbon in the layer of GaN 540 can be particularly low (or the lowest throughout the layer of GaN 540) at or near the interface between the layer of GaN 540 and the sub-barrier layer 550. If the sub-barrier layer 550 is omitted, concentration levels of iron and carbon in the layer of GaN 540 can be particularly low at or near the interface between the layer of GaN 540 and the barrier layer 560. In other examples, the iron concentration throughout the layer of GaN 540 or at or near the interface with the sub-barrier layer 550 can be less than the current detectability limit. In other cases, the iron concentration throughout the layer of GaN 540 or at or near the interface with the sub-barrier layer 550 can be less than or equal to 1×10¹⁵ cm⁻³, or less than or equal to 1×10¹⁶ cm⁻³. In still other cases, the iron concentration throughout the layer of GaN 540 or at or near the interface with the sub-barrier layer 550 can be less than 3×10¹⁶ cm⁻³, less than 4×10¹⁶ cm⁻³, or less than 5×10¹⁶ cm⁻³. In these examples, the iron can be intentionally added (in small amounts) or unintentionally present. In a similar manner, the carbon concentration throughout the layer of GaN 540 or at or near the interface with the sub-barrier layer 550 can be less than the current detectability limit. In other cases, the carbon concentration throughout the layer of GaN 540 or at or near the interface with the sub-barrier layer 550 can be less than or equal to 1×10¹⁶ cm⁻³, or less than or equal to 3×10¹⁶ cm⁻³. In still other cases, the iron concentration throughout the layer of GaN 540 or at or near the interface with the sub-barrier layer 550 can be less than 5×10¹⁶ cm⁻³.

The sub-barrier layer 550 can be embodied as a layer of AlN. The sub-barrier layer 550 can have a thickness of between 1-5 nm, or a narrower range, such as between 1-4 nm, between 1-3 nm, or between 1-2 nm. In one example, the sub-barrier layer 550 can have a thickness of 1 nm.

The barrier layer 560 can be embodied as a layer of AlGaN. The barrier layer 560 can have a thickness of between 5-30 nm, or a narrower range, such as between 5-25 nm or between 10-20 nm. In one example, the barrier layer 560 can have a thickness of 18 nm. The ratio of aluminum to gallium in the barrier layer 560 can be 25% aluminum to 75% gallium, for Al_{0.25}Ga_{0.75}N, although the ratio can vary. In other cases, the ratio of aluminum to gallium in the barrier layer 560 can range from 23-27% aluminum, with the balance gallium, and other ratios can be relied upon. The cap layer 570 can be embodied as a layer of GaN. The cap layer 570 is optional and can be omitted in some cases. The cap layer 570 can have a thickness of between 1-4 nm.

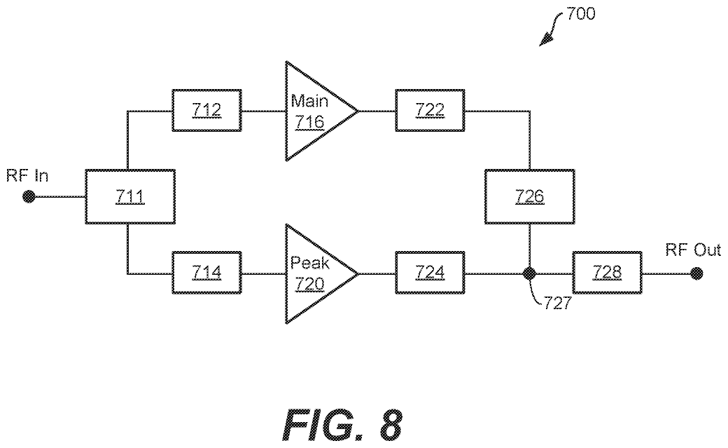

Amplifiers, and their component transistors, can be formed in or on the semiconductor material wafers described in FIGS. 5-7. Combinations of transistors can be used in a range of different types of amplifiers. As described herein, the semiconductor material wafers are optimized for use in certain applications, such as for transistors that do not exhibit (or exhibit less) distortions (e.g., ACP spurs), and/or do exhibit low EVM percentages during mobile communications. FIG. 8 illustrates an example amplifier, including one or more transistors formed in or on the semiconductor material wafers described in FIGS. 5-7.

FIG. 8 illustrates an example amplifier 700 according to various embodiments described herein. The amplifier 700 is provided as a representative example of an amplifier exhibiting improved characteristics, such as less ACP spurs and low EVM during mobile communications, among other improvements. The illustration in FIG. 8 is not exhaustive, and the amplifier 700 can include other components that are not shown. Additionally, one or more components shown in FIG. 8 can be omitted in some cases. The amplifier 700 can be formed in various ways, such as using discrete components, as an integrated circuit device formed on one or more semiconductor die, or as a combination of discrete components and integrated circuit devices. The amplifier 700 can also be packaged in a suitable semiconductor package, with or without other components.

The amplifier 700 is a Doherty amplifier. The amplifier 700 comprises a 90-degree power splitter 711, which divides a received RF input signal into two outputs that are coupled, respectively, to a main amplifier 716 and an auxiliary or peaking amplifier 720, arranged on parallel circuit branches. The power splitter 711 also delays (e.g., by approximately 90 degrees) the phase of the signal provided to the peaking amplifier 720 with respect to the phase of the signal provided to the main amplifier 716.

The amplifier 700 also includes impedance-matching components 712 and 714, which are coupled before the main amplifier 716 and peaking amplifier 720, respectively. The impedance-matching components match the output impedances of power splitter 711 to the input impedances of the main amplifier 716 and the peaking amplifier 720, to reduce signal reflections and other unwanted effects.

Additional impedance-matching components 722 and 724 are coupled at the outputs of the main amplifier 716 and the peaking amplifier 720, to match impedances among the main amplifier 716, the peaking amplifier 720, and the combining node 727. The impedance inverter 726 rotates the phase of the signal output from the main amplifier 716, so that the signals from the main amplifier 716 and the peaking amplifier 720 will be substantially in phase at the combining node 727. As shown in FIG. 8, an output impedance-matching component 728 can also be coupled between the combining node 727 and an output of the amplifier 700, to match the output impedance of the amplifier 700 to an impedance of a load (not shown).

By design, the peaking amplifier 720 is typically off at lower power levels, which can be handled by the main amplifier 716 alone. At higher power levels, the main amplifier 716 can become saturated, and the gain of the main amplifier 716 can be compressed, resulting in a loss of linearity for the amplifier 700. The compression point for the main amplifier 716 can vary depending upon its design. When the peaking amplifier 720 is on, it effectively adds load impedance to the main amplifier 716 (reducing the gain of the main amplifier 716) but also assists in extending the linearity of amplification to higher power levels.

In one example, the main amplifier 716 can be formed as a transistor formed in or on one of the semiconductor material wafers shown in FIGS. 5-7 and described above. The peaking amplifier 720 can also be formed as a transistor formed in or on one of the semiconductor material wafers shown in FIGS. 5-7 and described above. In that case, both the amplifiers 716 and 720 can be formed using the semiconductor material wafers shown in FIGS. 5-7. In another example, the main amplifier 716 can be formed as a transistor using one of the semiconductor material wafers shown in FIGS. 5-7, and the peaking amplifier 720 can be formed as a transistor using one of the semiconductor material wafers shown in FIGS. 3 and 4. In another example, the main amplifier 716 can be formed as a transistor using one of the semiconductor material wafers shown in FIGS. 3 and 4, and the peaking amplifier 720 can be formed as a transistor using one of the semiconductor material wafers shown in FIGS. 5-7.

Doherty amplifiers, including the amplifier 700, can be designed as symmetric or asymmetric. If symmetric, a Doherty amplifier can include main and auxiliary (carrier and peaking) transistors of the same design (e.g., the amplifiers 716 and 720 can be of the same power, size, layout, composition, construction, etc.). An asymmetric Doherty amplifier includes main and auxiliary transistors of different designs. In other cases, the transistors formed in or on the semiconductor material wafers shown in FIGS. 5-7 can be used to form amplifiers of different topologies, and the transistors are not limited to use with Doherty amplifiers.

It may be preferred that the Doherty amplifiers, including the amplifier 700, be formed using either or both the peaking amplifier 716 and main amplifier 720 using one or more transistors formed in the semiconductor material wafers shown in FIGS. 5-7. As discussed in FIGS. 5-7, the combined total thickness of the GaN layers is in the range of 600 to 1700 nm and as such, have lower threading dislocation defect densities and therefore less associated threading dislocation defect traps than in thinner iron and carbon free GaN layers. As such, the resulting structures lead to improved linearized performance levels.

Furthermore, it is desirable that the Doherty amplifier consisting of semiconductor material wafers shown in FIGS. 5-7 exhibit low peak and average linearized EVM percentages. It may be desirable for the linearized peak EVM percentage to be less than 6%. Utilizing the wafers formed in accordance with FIG. 5, it has been found that Doherty amplifiers may be formed that exhibit an average EVM percentage of between 1-2.5%. This level of performance is advantageous for denser modulation constellations, such as that used in 5G protocols and beyond. It may additionally be preferred that the Doherty amplifier exhibit these linearized EVM specifications at a temperature of 25 C, or preferably over a range of operating temperatures from −40 C to 130 C.

The transistors described herein can be formed as field effect transistors (FETs), although the concepts can be applied to other types of transistors. The transistors described herein can include one or more field plates, such as source-connected field plates, gate-connected field plates, or both source-connected and gate-connected field plates. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and for use as high efficiency power amplifiers. Other GaN-based or III-nitride-based FETs which may benefit from the semiconductor material substrates described herein include FETs for low frequency power devices used in power management applications, for example. The FETs can include metal oxide or insulator semiconductors (MOSFET or MISFET) transistors.

The transistors described herein can be formed using a number of different GaN or III-nitride materials and semiconductor manufacturing processes. The group III elemental semiconductor materials include aluminum (Al), gallium (Ga), and indium (In), and compounds thereof. Semiconductor transistor amplifiers can be constructed from group III-V direct bandgap semiconductor technologies, in certain cases, as the higher bandgaps and electron mobility provided by those devices can lead to higher electron velocity and breakdown voltages, among other benefits. Thus, in some examples, the concepts can be applied to group III-V direct bandgap active semiconductor devices, such as the III-nitrides (aluminum (Al)—, gallium (Ga)—, indium (In)—, and their alloy (AlGaln) based nitrides), GaAs, InP, InGaP, AlGaAs, etc., devices. However, the principles and concepts can also be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material” or GaN semiconductor material refers to gallium nitride and any of its alloys, the III-nitrides, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaASₐP_{b}N_{(1-a-b)}), aluminum indium gallium arsenide phosphide nitride (AlₓIn_{y}Ga_{(1-x-y)}ASₐP_{b}N_{(1-a-b)}), among others. Typically, when present, arsenic and/or phosphorous are at low concentrations (e.g., less than 5 weight percent). The term “gallium nitride” or GaN semiconductor refers directly to gallium nitride, exclusive of its alloys.

The features, structures, or characteristics described above may be combined in one or more embodiments in any suitable manner, and the features discussed in the various embodiments are interchangeable, if possible. In the foregoing description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well known structures, materials, or operations are not shown or described in detail to avoid obscuring aspects of the present disclosure.

Although relative terms such as “on,” “below,” “upper,” “lower,” “top,” “bottom,” “right,” and “left” may be used to describe the relative spatial relationships of certain structural features, these terms are used for convenience only, as a direction in the examples. It should be understood that if the device is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc., are used only as labels, rather than a limitation for a number of the objects.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

I/We claim:

1. An epiwafer comprising:
a substrate that includes at least a silicon carbide layer;
a nucleation layer over the silicon carbide layer;
a gallium nitride layer over the nucleation layer, having a thickness of greater than 600 nm and a concentration of iron that is less than or equal to 1×10¹⁶ cm⁻³; and
a barrier layer over the gallium nitride layer.

2. The epiwafer of claim 1 wherein the gallium nitride layer is about 800 nm.

3. The epiwafer of claim 1 wherein the barrier layer is comprised of a sub-barrier layer and a barrier layer, the sub-barrier layer being aluminum nitride having a thickness of about 1 nm and the main barrier layer being aluminum gallium nitride having a thickness of about 18 nm.

4. The epiwafer of claim 3 further including a cap layer over the barrier layer, the cap layer being gallium nitride having a thickness of about 2 nm.

5. The epiwafer of claim 1 wherein the silicon carbide layer is a 4H silicon carbide layer.

6. The epiwafer of claim 1 wherein the gallium nitride layer has a concentration of carbon less than 3×10¹⁶ cm⁻³.

7. The epiwafer of claim 1 wherein the gallium nitride layer is comprised of a first gallium nitride layer over the nucleation layer and a second gallium nitride layer over the first gallium nitride layer, further wherein the first gallium nitride layer is intentionally doped with carbon to a concentration of about 1×10¹⁸ to 5×10¹⁸ cm⁻³ and the second gallium nitride layer is not intentionally doped with carbon.

8. An epiwafer comprising:
a substrate that includes at least a silicon carbide layer;
a nucleation layer over the silicon carbide layer;
a gallium nitride layer over the nucleation layer, having a thickness of greater than 600 nm and wherein there is no intentional doping of the gallium nitride layer with any dopant intended to improve carrier confinement, increase breakdown voltage, or reduce unwanted leakage current; and
a barrier layer over the gallium nitride layer.

9. The epiwafer of claim 8 wherein the gallium nitride layer is about 800 nm.

10. The epiwafer of claim 8 wherein the barrier layer is comprised of a sub-barrier layer and a barrier layer, the sub-barrier layer being aluminum nitride having a thickness of about 1 nm and the main barrier layer being aluminum gallium nitride having a thickness of about 18 nm.

11. The epiwafer of claim 10 further including a cap layer over the barrier layer, the cap layer being gallium nitride having a thickness of about 2 nm.

12. The epiwafer of claim 8 wherein the silicon carbide layer is a 4H silicon carbide layer.

13. The epiwafer of claim 8 wherein the gallium nitride layer is comprised of a first gallium nitride layer over the nucleation layer and a second gallium nitride layer over the first gallium nitride layer, further wherein the first gallium nitride layer is intentionally doped with carbon to a concentration of about 1×10¹⁸ to 5×10¹⁸ cm⁻³ and the second gallium nitride layer is not intentionally doped with carbon.

14. A Doherty amplifier for amplifying an input signal comprising:
a power splitter for splitting the input signal into a main input signal and a peak input signal;
a main amplifier formed in an epiwafer for amplifying the main input signal;
a peaking amplifier formed in the epiwafer for amplifying the peak input signal; and
a combining node to receive the output of the main amplifier and the peaking amplifier;
wherein the epiwafer comprises:
a substrate that includes at least a silicon carbide layer;
a nucleation layer over the silicon carbide layer;
a gallium nitride layer over the nucleation layer, having a thickness of greater than 600 nm and wherein there is no intentional doping of the gallium nitride layer with any dopant intended to improve carrier confinement, increase breakdown voltage, or reduce unwanted leakage current; and
a barrier layer over the gallium nitride layer.

15. The amplifier of claim 14 wherein the gallium nitride layer is about 800 nm.

16. The amplifier of claim 14 wherein the barrier layer is comprised of a sub-barrier layer and a barrier layer, the sub-barrier layer being aluminum nitride having a thickness of about 1 nm and the main barrier layer being aluminum gallium nitride having a thickness of about 18 nm.

17. The amplifier of claim 16 further including a cap layer over the barrier layer, the cap layer being gallium nitride having a thickness of about 2 nm.

18. The amplifier of claim 14 wherein the silicon carbide layer is a 4H silicon carbide layer.

19. The amplifier of claim 14 wherein the gallium nitride layer is comprised of a first gallium nitride layer over the nucleation layer and a second gallium nitride layer over the first gallium nitride layer, further wherein the first gallium nitride layer is intentionally doped with carbon to a concentration of about 1×10¹⁸ to 5×10¹⁸ cm⁻³ and the second gallium nitride layer is not intentionally doped with carbon.
